(19) United States
(12) Patent Application Publication
(10) Pub. No.: US 2011/0038122 A1
(43) Pub. Date: Feb. 17, 2011

(54) Phase Change Heat Spreader Bonded to Power Module by Energetic Multilayer Foil

(75) Inventors: Abdolmehdi Kaveh Ahangar, Brown Deer, WI (US); Steven C. Kaishian, Wauwatosa, WI (US)

Correspondence Address: Susan M. Donahue;Rockwell Automation, Inc./FY, 1201 South Second Street, E-7F19, Milwaukee, WI, 53204, US

(73) Assignee: ROCKWELL AUTOMATION TECHNOLOGIES, INC., Mayfield Heights, OH (US)

(21) Appl. No.: 12/540,134

(22) Filed: Aug. 12, 2009

(51) Int. Cl. H05K 7/20; B23P 11/00

(52) U.S. Cl. 361/700; 29/525.14

(57) ABSTRACT

Power electronic devices are solder to a phase change heat spreader using an energetic multilayer foil. This foil may be sandwiched between layers of solder, the first layer in contact with the power electronic devices and the second layer in contact with the phase change heat spreader. When activated, this foil may induce the solder to physically and thermally bond the power electronic devices to the phase change heat spreader. Certain embodiments may also employ energetic multilayer foil to thermally bond the phase change heat spreader to a heat dissipation structure. Other embodiments may employ a phase change heat spreader with an integrated heat dissipation structure. In addition, some embodiments may employ a heat sink as the heat dissipation structure, while other embodiments employ a liquid cooling system.

### BACKGROUND

The present invention relates generally to the field of power electronic devices and their thermal management. More particularly, the invention relates to a technique for improving cooling and isothermal heat distribution in power electronic modules.

Power electronic devices and modules are used in a wide range of applications. For example, in electric motor controllers, switches and diodes are employed to define rectifiers, inverters, and more generally, power converters. Depending upon the size and rating of the circuits and components used in power electronic circuits, a plurality of components are typically disposed on a common support or substrate to form a module. The module may, itself and by the interconnection of the associated components, form a rectifier, a portion of a rectifier, an inverter, one leg of an inverter, a collected set of switches for an inverter, or similar subsystems for converters.

A continuing issue in such devices is the management of heat that is generated by conduction and switching of the power electronic components. In general, internal conduction and switching losses will generate heat during operation which must be channeled from the components and limited to protect the components from damage and to extend their useful life. This is typically done by associating a substrate or module on which the components are disposed (e.g., direct bond copper (DBC)) with some sort of heat sink. Monolithic, finned, and other heat sinks are typically bolted, bonded or soldered to the substrate and serve to draw heat away from the components, spread heat to some limited extend, and transfer heat to the environment.

While such structures do function to reduce the heat generated by power electronic components, increasing power density of devices, and increased power ratings have extended these techniques to their physical limits. To better distribute heat from the power electronic devices to the heat sink, a phase change heat spreader may be employed. This device includes an evaporating surface adjacent to the heat source, a condensing surface adjacent to the heat sink and a working liquid that transfers heat between the two surfaces. The working liquid in contact with the evaporating surface absorbs heat from the heat source as it evaporates. The vapor is then transferred to the condensing surface where it cools and condenses. The liquid is then transferred back to the evaporating surface, where the process repeats. In this manner, the phase change heat spreader provides an effective means of transferring heat from the power electronic devices to the heat sink.

However, efficiency of the phase change heat spreader may be dependent on the thermal conductivity of the bond between the evaporating surface and the heat source, and the condensing surface and the heat sink. Present thermal coupling techniques include applying a layer of thermal grease between components and securing them with bolts. However, the thermal conductivity of grease is relatively low. Furthermore, grease tends to degrade and/or leak out of the connection over time, reducing the effectiveness of the thermal bond.

Alternatively, a soldered connection may provide enhanced thermal conductivity and a longer lasting bond. However, present soldering techniques are problematic with regard to phase change heat spreaders. For example, soldering typically involves applying a layer of solder between components and placing the components in an oven. The oven heats the solder (and the components) creating a bond. However, heating a phase change heat spreader is undesirable because it contains a liquid. Heating may cause the liquid to vaporize, thereby over-pressurizing and potentially forming leaks within the phase change heat spreader.

One solution to this over-pressurization problem is to solder the components to the phase change heat spreader before filling it with the working liquid. However, this technique is undesirable because it may require sending the phase change heat spreader back to its manufacturer after the components have been attached. Shipping is expensive, delays construction and increases the possibility that components may be damaged during transit.

There is a need, therefore, for improved techniques for thermally coupling components to a phase change heat spreader.

### BRIEF DESCRIPTION

The invention provides a novel approach to power electronic module thermal management designed to respond to such needs. The technique may be applied in a wide range of settings, but is particularly well-suited to power converters, inverters, and similar circuits. The technique relies upon a phase change heat spreader that utilizes evaporation and condensation to transfer heat from one plate-like side to another plate-like side, the first plate structure forming an evaporator, and the second plate structure forming a condenser. A continuous phase change cycle takes place in the device to continuously extract heat from the power electronic module. The phase change heat spreader extends over a surface of the power electronic module to be cooled, and by operation of the phase change both extracts heat and significantly reduces temperature differences within regions of the power electronic module base, rendering the overall system more isothermal. In certain embodiments, the phase change heat spreader replaces a base plate of the power electronic module such that components of the power electronic module are mounted directly to the phase change heat spreader.

Effective thermal coupling between the phase change heat spreader and the power electronic devices (e.g., DBC) may increase efficiency of the phase change heat spreader, facilitating greater heat transfer to the heat dissipation structure. Enhanced thermal coupling may be achieved by soldering the power electronic devices to the phase change heat spreader using an energetic multilayer foil. This foil may be sandwiched between layers of solder, the first layer in contact with the power electronic devices and the second layer in contact with the phase change heat spreader. When activated, the foil may induce the solder to physically and thermally bond the power electronic devices to the phase change heat spreader. This soldering technique may minimize heat transfer to the phase change heat spreader during the soldering process, thus reducing the probability of over-pressurization inherent in conventional soldering methods.

Certain embodiments may also employ energetic multilayer foil to thermally bond the phase change heat spreader to the heat dissipation structure. Other embodiments may employ a phase change heat spreader with an integrated heat dissipation structure. In addition, some embodiments may employ an air cooled heat sink as the heat dissipation structure, while other embodiments may employ a liquid cooling system.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatical side view of a power electronic module utilizing a phase change heat spreader in accordance with aspects of the invention;

FIG. 2 is a top view of the device of FIG. 1;

FIG. 3 is a sectional view through an exemplary phase change heat spreader for use in any one of the applications envisaged by the invention;

FIG. 4 is a diagrammatical side view of the power electronic module of FIG. 1 utilizing thermal bonds containing energetic multilayer foil;

FIG. 5 is a diagrammatical side view of an alternative power electronic module utilizing thermal bonds containing energetic multilayer foil;

FIG. 6 is a diagrammatical side view of a further power electronic module utilizing thermal bonds containing energetic multilayer foil;

FIG. 7 is a graph of temperature as a function of distance from the energetic multilayer foil; and

FIG. 8 is a graph of temperature within a phase change heat spreader as a function of time after foil activation.

### DETAILED DESCRIPTION

Embodiments of the present disclosure may significantly reduce heat transfer to a phase change heat spreader during a bonding process. In certain embodiments, an electronic power module includes a power electronic device and a phase change heat spreader. The power electronic device may be thermally coupled to the phase change heat spreader by a thermal bond, including a first solder layer, a second solder layer and an energetic multilayer foil disposed between the solder layers. When activated, the energetic multilayer foil generates heat that temporarily liquefies the solder layers. As the solder layers fuse and resolidify, the power electronic device may be coupled to the phase change heat spreader. As discussed in detail below, heat from the energetic multilayer foil is substantially restricted to the solder layers. Therefore, a working liquid within the phase change heat spreader may remain relatively cool throughout the foil activation process, thereby limiting the pressure within the phase change heat spreader. Consequently, the present technique facilitates bonding power electronic devices to a pre-filled phase change heat spreader.

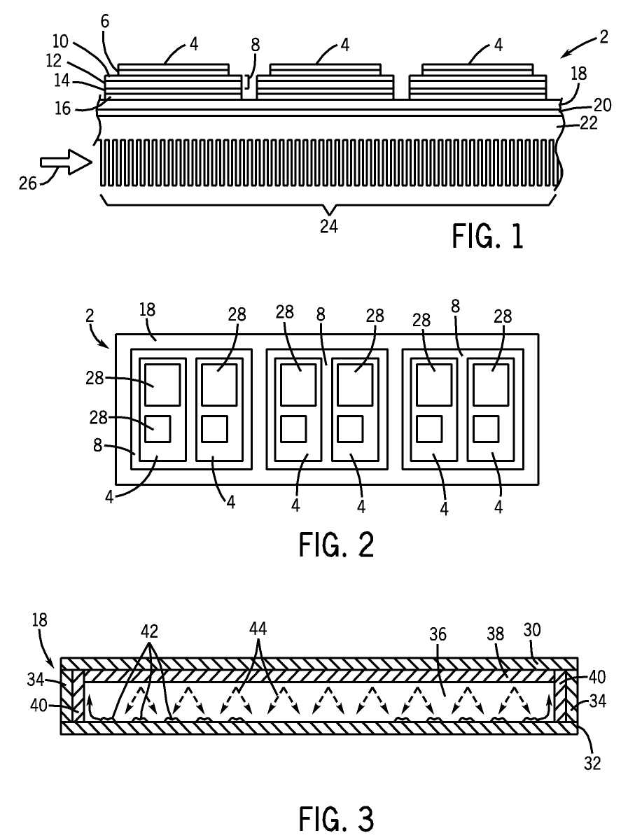

Turning now to the drawings, FIG. 1 illustrates an exemplary embodiment in which a phase change heat spreader is added to a preassembled power electronic module. The module 2 illustrated in FIG. 1 includes a series of power electronic devices or chips 4 that are disposed via a solder connection 6 on an underlying direct bond copper (DBC) substrate 8, including a conductive (copper) layer 10 on a ceramic layer 12. The ceramic layer 12, then, has a further conductive (copper) layer 14 bonded to it. A further solder layer 16 thermally couples the stack to the phase change heat spreader 18. This solder layer includes an energetic multilayer foil sandwiched between two solder layers. Activation of the foil induces solder layer 16 to physically and thermally bond the DBC substrate 8 to the phase change heat spreader 18. While each stack is directly coupled to the phase change heat spreader 18 in the present embodiment, alternative embodiments may employ a common support or substrate disposed between the stacks and the phase change heat spreader 18. In such embodiments, the stacks may be physically coupled to the common support, and the common support may be bonded to the phase change heat spreader 18 by the solder layer 16, thereby thermally coupling each stack to the phase change heat spreader 18. The phase change heat spreader 18 may, in turn, be mounted on a heat dissipation structure 22 (e.g., heat sink) by means of a soldered connection 20. Similar to solder layer 16, solder layer 20 may employ an energetic multilayer foil to bond the respective components.

Certain locations, components, modules or subsystems of the power electronic devices 4 may make use of a phase change heat spreader 18 in accordance with aspects of the invention. In general, such devices may be employed to improve heat transfer from heat sources, such as switched components, un-switched components, busses and conductors, connection points, and any other source of heat. As will be appreciated by those skilled in the art, during operation many of the components of such circuitry may produce heat generally by conduction losses in the component, or between components. Such heat will generally form hot spots, which may be thought of as regions of high thermal gradient. Conventional approaches to extracting heat to reduce the temperature of such sources include extracting heat by conduction in copper or other conductive elements, circulation of air or other fluids, such as water, and so forth. The present approach makes use of a phase change heat spreader 18 that not only improves the extraction of heat from such sources, but aids in distributing the heat to render the heat sources and neighboring areas of the circuitry more isothermal.

Further thermal management structures may be provided, such as fins 24 over which an air flow 26 may be directed. Other arrangements may include various known fin or heat dissipating structures, liquid cooling arrangements, and so forth. The configuration of heat sink 22 may be varied based on design considerations. For example, heat sink 22 may be constructed of copper and/or aluminum, etc. Heat sink 22 may include integral fins 24 or fins 24 thermally coupled to a base member. The base member and/or fins 24 may be composed of any suitable thermally conductive material. For example, in one embodiment, heat sink 22 may include a solid aluminum base with integral aluminum fins 24. In another embodiment, heat sink 22 may include aluminum fins 24 thermally bonded to a copper base member. The size and number of fins 24 may vary based on a variety of factors, including the quantity of heat produced by the power electronic devices 4 and the magnitude of air flow 26 over heat sink 22, among others. In addition, air may naturally flow through heat sink 22 or air flow 26 may be induced by a fan and/or blower, etc.

In alternative embodiments, the phase change heat spreader 18 may be replaced by a monolithic base plate composed of a thermally conductive material (e.g., copper). As will be appreciated, soldering components (e.g., DBC) to such a base plate my cause the base plate to deform due to the heat and/or thermal disparity between the components and the base plate. Consequently, the base plate may be deformed prior to soldering such that heat from the soldering operation results in a substantially flat base plate. Unfortunately, such an operation increases construction costs associated with component mounting. Therefore, certain embodiments may employ a solder layer including the energetic multilayer foil to bond the components to the base plate, thereby obviating the initial deformation of the base plate and providing a substantially flat surface to mount various heat dissipation structures.

An exemplary top view of the embodiment depicted in FIG. 1 is shown in FIG. 2. Here again, the phase change heat spreader 18 may be seen below the DBC substrates 8 on which the power electronics circuits in the prepackaged chips 4 are positioned. The chips 4 in the embodiment illustrated in FIG. 2, are designed to incorporate electrical components 28, including switches and diodes. These components 28 may function together to form rectifiers and/or inverters. For example, diodes may form a rectifier to convert three-phase AC input power to DC power that is applied to a DC bus. Similarly, an inverter circuit may be formed by an array of switches and associated fly-back diodes. Other circuits, including converters, AC-to-AC circuitry, AC-to-DC circuitry, DC-to-AC circuitry, and DC-to-DC circuitry may also be employed.

As noted above, the phase change heat spreader with a full or partial power electronic module enables heat to be extracted from hot spots in the module and distributed more evenly over the module surface. The modules thus associated with phase change heat spreaders have been found to operate at substantially lower temperatures, with temperatures of hot spots being particularly lowered by virtue of the distribution of heat to a greater surface area owing to the action of the phase change heat spreader.

An exemplary phase change heat spreader is illustrated in FIG. 3. An exemplary phase change heat spreader 18 suitable for use in the embodiments of the invention will typically be positioned immediately adjacent to a hot substrate or device layer to be cooled. Ultimately, as described below, the underlying structures reduce thermal gradients and more evenly distribute heat for improved heat extraction. The phase change heat spreader 18, itself, is formed of an evaporator plate 30 disposed in facing relation and space from a condenser plate 32. Sides 34 extend between the plates to hold the plates in a fixed mutual relation and to sealingly close an internal volume 36. A primary wick structure 38 is disposed immediately adjacent to the evaporator plate 30, and secondary wick structures 40 extend between the condenser plate 32 and primary wick structure 38. It should be noted that another section of the secondary wick structure (not shown in the figures) may extend over all or a portion of the condenser plate.

The various materials of construction for a suitable phase change heat spreader may vary by application, but will generally include materials that exhibit excellent thermal transfer properties, such as copper and its alloys. The wick structures may be formed of a similar material, and provide spaces, interstices or sufficient porosity to permit condensate to be drawn through the wick structures and brought into proximity of the evaporator plate. Presently contemplated materials include metal meshes, sintered metals, such as copper, and so forth. The wick structure may be integrated into a body portion of the phase change heat spreader. The body portion may also include the evaporating surface and the sides. A cover plate including the condensing surface may be coupled to the body portion to seal the heat spreader. In certain embodiments, the cover plate may be bonded to the body portion by a solder layer. This solder layer may include an energetic multilayer foil sandwiched between two layers of solder. When activated, this foil may induce the solder to physically and thermally bond the cover plate to the body portion.

In operation, a cooling fluid, such as water, is sealingly contained in the inner volume 36 of the device and the partial pressure reigning in the internal volume allows for evaporation of the cooling fluid from the primary wick structure due to heating of the evaporator plate. Vapor released by the resulting phase change will condense on the secondary wick structure and the condenser plate, resulting in significant release of heat to the condenser plate. To complete the cycle, the condensate, indicated generally by reference numeral 42 in FIG. 3, will eventually reach the secondary wick structures through which it will be transferred to the primary wick structure to be re-vaporized as indicated by reference numeral 44. A continuous thermal cycle of evaporation and condensation is thus developed to effectively cool the evaporator plate and transfer heat to the condenser plate. Because the evaporator plate extends over an area that includes local hot spots, heat is evenly distributed over the surface area of the condenser plate.

It should be noted that, as mentioned above, and in further embodiments described below, the phase change heat spreader may be designed as an “add-on” device, or may be integrated into the design of one of the components (typically as a support or substrate). Similarly, the fins on the various structures described herein may be integral to the heat spreader, such as with the condenser plate. Also, the cooling media used within the heat spreader may include various suitable fluids, and water-based fluids are one example only. Finally, the ultimate heat removal, such as via the fins or other heat dissipating structures, may be to gasses, liquids, or both, through natural of forced convection, or a combination of such heat transfer modes. More generally, the fins described herein represent one form of heat dissipation structure, while others may be used instead or in conjunction with such fins. For example, in certain embodiments, the fins may be pin-shaped, plate-shaped, or otherwise configured to provide effective heat dissipation.

The phase change heat spreader of FIG. 3 may be used in any one or all of the settings contemplated by the present discussion. That is, such a device may extend over all or a portion of a power module, several power modules mounted on a DBC or, more generally, any power electronic circuitry. Devices of this type may be used for specific cooling locations, such as conductors and busses. Similarly, locations such as attachment points for wire bond conductors, at which point heat may be generated due to resistive losses, may also benefit from individual, even relatively small phase change heat spreaders. Moreover, as discussed below, specific components may be associated with individual phase change heat spreaders, such as brake resistors, and so forth.

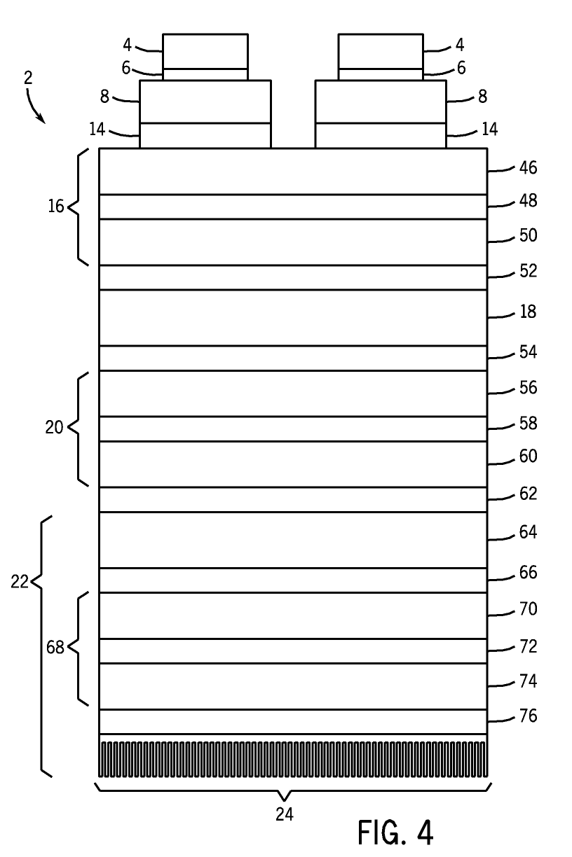

FIG. 4 is a diagrammatical view of the layers which may be employed to bond the power electronic devices to the phase change heat spreader, and to bond the phase change heat spreader to the heat dissipation structure. As described above, the electronic devices 4 may be coupled to the DBC layer 8 by a solder connection 6. In certain embodiments, the DBC layer 8 may include a copper base 14. In other embodiments, the base of the DBC layer 8 may be coated with tin (e.g., immersion tin) or gold alloy. The gold alloy coating may include a combination of electroless nickel and immersion gold (ENIG). These coatings and/or the copper base 14 may facilitate proper bonding between solder layer 16 and the DBC layer 8. Other base materials and coatings may also be employed in alterative embodiments.

The DBC layer 8 may be physically and thermally coupled to the phase change heat spreader 18 by solder layer 16. This solder layer may include a first solder layer 46, an energetic multilayer foil 48 and a second solder layer 50. The energetic multilayer foil 48 may include alternating microscopic (nanoscale) layers of aluminum and nickel. When activated, a chemical reaction between the foil layers may release heat, temporarily liquefying solder layers 46 and 50. As the solder layers fuse and resolidify, the DBC layer 8 may be coupled to the phase change heat spreader 18. Products of the chemical reaction may include an aluminum-nickel alloy which may become embedded in the solder layers as they fuse. The foil 48 may be activated by applying an electrical current. For example, once the foil 48 is placed between solder layers 46 and 50, a nine volt (9V) battery may be employed to activate the foil 48. A first electrode may be connected to a negative terminal of the battery and a second electrode may be connected to a positive terminal. When the two electrodes contact the foil 48, the resultant electrical current may activate the foil 48, generating heat and producing the above described alloy. One foil 48 of this type is NanoFoil® manufactured by Reactive Nano Technologies.

A second coating 52 may be applied to the phase change heat spreader 18 to facilitate coupling with solder layer 16. This coating may include tin or a tin alloy. For example, coating 52 may include a eutectic lead-tin plating. Alternatively, the phase change heat spreader 18 may include a copper evaporator plate. The copper structure and/or tin/tin alloy coating may facilitate effective bonding between solder layer 16 and the phase change heat spreader 18. Similarly, a coating 54 may be applied to the condenser plate of the phase change heat spreader 18 to facilitate bonding to solder layer 20. Coating 54 may also include tin or a tin alloy.

Similar to solder layer 16, solder layer 20 may include a first solder layer 56, an energetic multilayer foil 58 and a second solder layer 60. These layers may facilitate a physical and thermal bond between the phase change heat spreader 18 and the heat dissipation structure 22. The heat dissipation structure 22 may include a coating 62 similar to coating 52 described above. This coating, including tin or a tin alloy, for example, may facilitate proper bonding between solder layer 20 and the heat dissipation structure 22. In certain embodiments, the top surface of the heat dissipation structure is composed of copper and coating 62 is omitted.

As previously discussed, the heat dissipation structure 22 may include a heat sink. FIG. 4 presents such a heat sink 22 which includes fins 24 attached to a base member 64 by a solder layer 68. In such a configuration, a tin/tin alloy coating 66, for example, may be applied to base member 64 to facilitate bonding. Solder layer 68 may utilize the same layered structure described above with regard to layers 16 and 20. Solder layer 68 may include a first solder layer 70 adjacent to base member 64, a layer of energetic multilayer foil 72 adjacent to the first solder layer 70, and a second solder layer 74 adjacent to the multilayer foil 72. Another coating 74 of tin or a tin alloy, for example, may serve to effectively bond fins 24 to solder layer 68. In one embodiment, base member 64 is composed of copper and fins 24 are composed of aluminum. In this configuration, coating 66 may be omitted, but coating 76 may facilitate proper bonding between solder layer 68 and aluminum fins 24. Other configurations may employ an aluminum base member 64 coupled to aluminum fins 24. Such a configuration may utilize both coatings 66 and 76.

In other embodiments, fins 24 may be integrally connected to base member 64. In such a configuration, thermal bond 68 and coatings 66 and 76 may be omitted. For example, the heat sink 22 may include one aluminum or copper structure having both a base member 64 and integrated fins 24. Other thermally conductive materials may also be employed to dissipate heat generated by the power electronic devices 4.

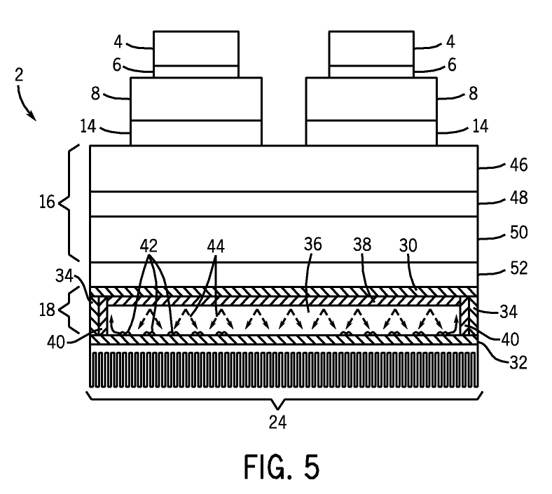

FIG. 5 depicts an embodiment similar to FIG. 4, except the phase change heat spreader includes an integral heat dissipation structure. Specifically, fins 24 are coupled to the condenser plate 32 of the phase change heat spreader 18. In this configuration, the condenser plate 32 may serve as a base member of the heat sink and function to dissipate heat. In the embodiment depicted in FIG. 5, fins 24 are composed of copper and are integrally connected to the condenser plate 32. In another embodiment, fins 24 are composed of aluminum and are thermally coupled to the condenser plate 32. In such an embodiment, the thermal bond may include an energetic multilayer foil sandwiched between two layers of solder. As previously discussed, if the condenser plate 32 is composed of copper, a solder layer may be directly applied to the surface. However, other condenser plate materials may be coated with tin or a tin alloy similar to coating 52 to facilitate bonding. Aluminum fins 24 may be similarly coated, while copper fins 24 may be bonded directly to the solder layer. Furthermore, both the phase change heat spreader 18 and fins 24 may be composed of other thermally conductive materials.

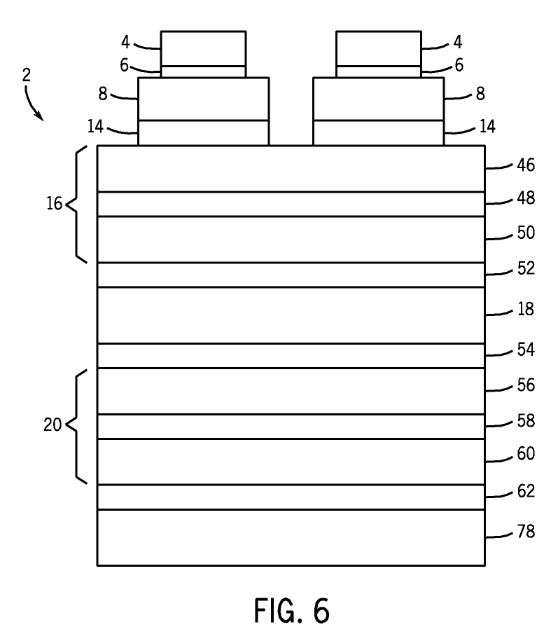

FIG. 6 depicts an embodiment of a power electronic module 2 which employs a liquid cooling system 78 to dissipate heat generated by the power electronic devices 4. The embodiment depicted in FIG. 6 is similar to the embodiment shown in FIG. 4, except a liquid cooling system 78 replaces the heat sink 22. In a liquid cooling system, a working liquid circulates through a series of passages, drawing heat from the phase change heat spreader 18. Liquid cooling systems typically employ pumps to circulate the working liquid. The liquid cooling system 78 may be thermally coupled to the phase change heat spreader 18 by thermal bond 20 described above. In addition, the liquid cooling system 78 may include a coating 62 of tin or a tin alloy, for example, to facilitate bonding to solder layer 20.

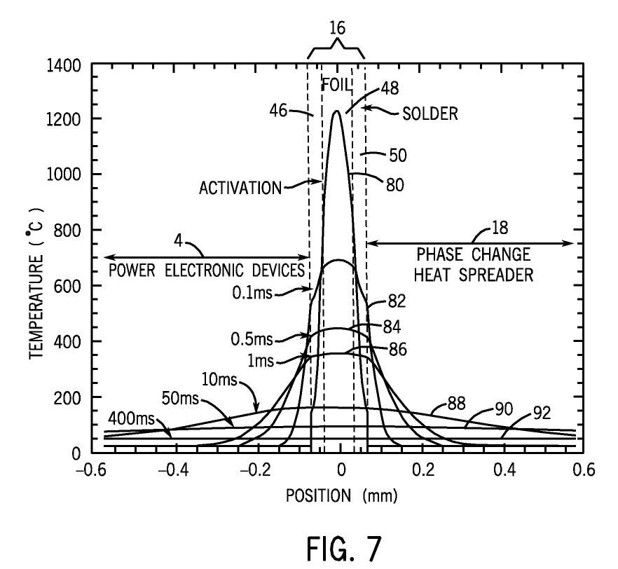

FIG. 7 presents a series of traces depicting temperature as a function of distance from the energetic multilayer foil 48. Each trace shown in this figure represents a particular time interval after activation of the foil 48. As seen in FIG. 7, the abscissa is centered around the centerline of solder layer 16. As previously discussed, the energetic multilayer foil 48 is surrounded on either side by solder layers 46 and 50. Power electronic devices 4 are located adjacent to solder layer 46, while the phase change heat spreader 18 is located adjacent to solder layer 50. In the embodiment depicted in FIG. 7, the foil 48 is approximately 0.08 mm thick and the solder layers are approximately 0.04 mm thick. In other embodiments, thickness of the foil 48 and solder layers 46 and 50 may vary.

Trace 80 represents a temperature profile through the above described layers immediately after the energetic multilayer foil 48 is activated. As seen in this figure, maximum temperature occurs at the approximate center of the foil 48 and is about 1250 degrees Celsius. However, this temperature decreases rapidly as distance from the center of the foil 48 increases. As a result, temperature at the boundary between the foil 48 and solder layer 50 is approximately 900 degrees Celsius. Temperature decreases further through solder layer 50, such that the temperature is approximately 150 degrees Celsius at the boundary between solder layer 50 and the phase change heat spreader 18.

Trace 82 represents a temperature profile 0.1 ms after foil activation. As this trace demonstrates, maximum foil temperature has already decreased to approximately 700 degrees Celsius 1/10,000th of a second after foil activation. However, temperature at the boundary between solder layer 50 and the phase change heat spreader 18 has increased to approximately 550 degrees Celsius. While temperature at the surface of the phase change heat spreader 18 is relatively high, the temperature approximately 0.075 mm into the surface is approximately 25 degrees Celsius, about room temperature.

Trace 84 indicates that at 0.5 ms, maximum temperature of the energetic multilayer foil 48 has fallen to approximately 450 degrees Celsius. At the interface between solder layer 50 and the phase change heat spreader 18, the temperature at 0.5 ms is approximately 400 degrees Celsius. At 1 ms, trace 86 indicates that maximum foil temperature and temperature at the boundary are approximately 350 degrees Celsius. Trace 88 shows that maximum foil temperature and boundary temperature at 10 ms are approximately 175 degrees Celsius. At 50 ms, trace 90 indicates that these temperatures have fallen to approximately 100 degrees Celsius. Finally, at 400 ms, curve 92 shows that temperatures have decreased to approximately 50 degrees Celsius.

The traces depicted in FIG. 7 indicate that foil temperature and boundary temperature decrease rapidly after foil activation. Furthermore, while foil temperature may be high, the temperature of the phase change heat spreader 18, only a fraction of a millimeter from the surface, is relatively low. For example, maximum temperature of the phase change heat spreader 18 at a distance of 0.5 mm from the surface is approximately 75 degrees Celsius at 50 ms. By 400 ms, the temperature has dropped to approximately 50 degrees Celsius. Therefore, the working liquid within the phase change heat spreader 18 may remain relatively cool throughout the foil activation process. Similar temperature profiles to those described above with regard to solder layer 16 may also be seen in solder layer 20.

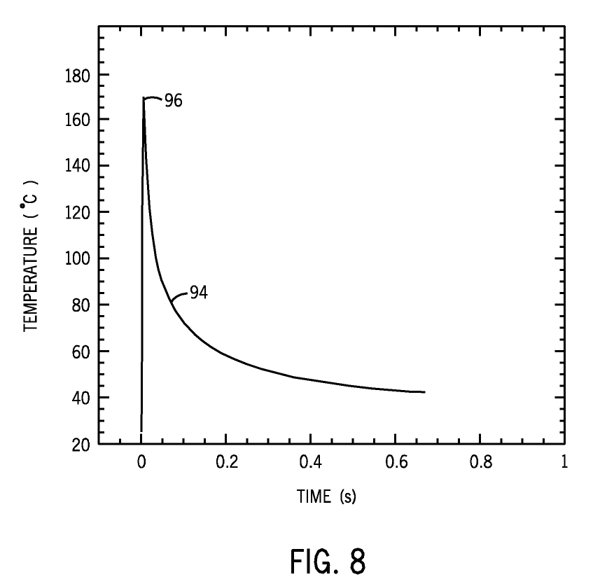

FIG. 8 is a graph of temperature versus time for a point 0.1 mm from the surface of the phase change heat spreader. As depicted by trace 94, maximum temperature 96 is approximately 170 degrees Celsius and occurs at the approximate time of foil activation. However, temperature at this location decreases rapidly with time. For example, curve 94 demonstrates that at 0.2 seconds after foil activation, the temperature has already decreased to approximately 60 degrees Celsius. At 0.4 seconds, temperature has dropped to 50 degrees Celsius, and at 0.6 seconds, temperature has fallen to 40 degrees Celsius. Because temperature decreases rapidly, only a small amount of heat may be transferred from the energetic multilayer foil to the phase change heat spreader. This small heat transfer may limit the temperature increase of the working liquid within the phase change heat spreader. Therefore, pressure within the phase change heat spreader during bonding may be lower than conventional soldering techniques. Furthermore, any heat transferred to the evaporator side of the phase change heat spreader may be quickly conveyed to the condenser side by the internal mechanism of the heat spreader, further reducing working liquid temperature and pressure.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An electronic power module comprising:
a power electronic device; and
a phase change heat spreader having a first side thermally coupled to the power electronic device by a thermal bond, and a second side opposite the first side;
wherein the thermal bond comprises a first solder layer, a second solder layer and an energetic multilayer foil disposed therebetween.

2. The electronic power module of claim 1, wherein the power electronic device is mounted directly onto the first side of the phase change heat spreader.

3. The electronic power module of claim 1, wherein the power electronic device comprises a tin or gold alloy coating on a surface adjacent to the thermal bond.

4. The electronic power module of claim 1, wherein the power electronic device comprises a copper layer adjacent to the thermal bond.

5. The electronic power module of claim 1, wherein the phase change heat spreader comprises a copper surface adjacent to the thermal bond.

6. The electronic power module of claim 1, wherein the phase change heat spreader comprises a tin or tin alloy coating on a surface adjacent to the thermal bond.

7. The electronic power module of claim 1, comprising a heat dissipation structure configured to dissipate heat generated by the device, the heat dissipation structure being coupled to the second side of the phase change heat spreader by a second thermal bond, the second thermal bond comprising a first solder layer, a second solder layer and an energetic multilayer foil disposed therebetween.

8. The electronic power module of claim 7, wherein the heat dissipation structure comprises a copper surface adjacent to the second thermal bond.

9. The electronic power module of claim 7, wherein the heat dissipation structure comprises a tin or tin alloy coating on a surface adjacent to the second thermal bond.

10. The electronic power module of claim 7, wherein the heat dissipation structure comprises a heat sink configured to transfer heat from the power electronic device to surrounding air.

11. The electronic power module of claim 10, wherein the heat sink comprises fins coupled to a base member by a thermal bond, wherein the thermal bond comprises a first solder layer, a second solder layer and an energetic multilayer foil disposed therebetween.

12. The electronic power module of claim 1, wherein the phase change heat spreader includes an evaporator side adjacent to the thermal bond, a wick structure for channeling condensate to the evaporator side, a condenser side opposite the evaporator side, and a cooling medium sealed between the evaporator side and the condenser side at a partial pressure that permits evaporation and condensation of the cooling medium during operation.

13. The electronic power module of claim 12, wherein the wick structure includes a primary wick structure disposed adjacent to the evaporator side and a secondary wick structure extending from the condenser side to the primary wick structure for wicking the cooling medium from the condenser side to the primary wick structure.

14. An electronic power module comprising:
a plurality of power electronic devices; and
a phase change heat spreader having a first side thermally coupled to the devices by a thermal bond, and a second side comprising a heat dissipation structure configured to dissipate heat from the devices;
wherein the thermal bond comprises a first solder layer, a second solder layer and an energetic multilayer foil disposed therebetween.

15. The electronic power module of claim 14, wherein the power electronic devices are mounted directly onto the first side of the phase change heat spreader.

16. The electronic power module of claim 14, wherein the phase change heat spreader includes an evaporator side adjacent to the thermal bond, a wick structure for channeling condensate to the evaporator side, a condenser side opposite the evaporator side, and a cooling medium sealed between the evaporator side and the condenser side at a partial pressure that permits evaporation and condensation of the cooling medium during operation.

17. The electronic power module of claim 16, wherein the wick structure includes a primary wick structure disposed adjacent to the evaporator side and a secondary wick structure extending from the condenser side to the primary wick structure for wicking the cooling medium from the condenser side to the primary wick structure.

18. The electronic power module of claim 14, wherein the heat dissipation structure comprises a heat sink configured to transfer heat from the power electronic devices to surrounding air.

19. The electronic power module of claim 18, wherein the heat sink comprises fins coupled to the second side of the phase change heat spreader by a thermal bond, wherein the thermal bond comprises a first solder layer, a second solder layer and an energetic multilayer foil disposed therebetween.

20. An electronic power module comprising:
a phase change heat spreader;
a plurality of power electronic devices thermally coupled to a first side of the phase change heat spreader by a first thermal bond; and
a liquid cooling system thermally coupled to a second side of the phase change heat spreader opposite the first side by a second thermal bond, and configured to dissipate heat generated by the devices;
wherein each thermal bond comprises a first solder layer, a second solder layer and an energetic multilayer foil disposed therebetween.

21. The electronic power module of claim 20, wherein the power electronic devices are mounted directly onto the first side of the phase change heat spreader.

22. The electronic power module of claim 20, wherein the power electronic devices comprise a tin or gold alloy coating on a surface adjacent to the first thermal bond.

23. The electronic power module of claim 20, wherein the liquid cooling system comprises a tin or tin alloy coating on a surface adjacent to the second thermal bond.

24. A method for making an electronic power module comprising:
mounting a plurality of power electronic devices to a first side of a phase change heat spreader by a thermal bonding process;
wherein the thermal bonding process comprises applying a first solder layer to a surface of the devices, applying a second solder layer to a surface of the phase change heat spreader, applying an energetic multilayer foil between the first and second solder layers, and activating the foil to physically and thermally bond the surfaces.

25. The method of claim 24, comprising mounting a heat dissipation structure to a second side of the phase change heat spreader opposite the first side by the thermal bonding process.
